(19) United States
(12) Patent Application Publication
(10) Pub. No.: US 2006/0267019 A1
(43) Pub. Date: Nov. 30, 2006

(54) Capacitor and methods of manufacturing the same

(75) Inventors: Kyoung-Seok Kim, Seoul (KR); Yong-Woo Hyung, Yongin-si (KR); Jae-Young Park, Yongin-si (KR); Hyeon-Deok Lee, Seoul (KR); Ki-Vin Im, Suwon-si (KR); Wook-Yeol Yi, Dong-gu (KR); Ko-Eun Lee, Suwon-si (KR); Young-Jin Kim, Suwon-si (KR); Seok-Woo Nam, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/434,921

(22) Filed: May 17, 2006

(30) Foreign Application Priority Data
May 30, 2005 (KR) 2005-45383

(51) Int. Cl. H01L 27/108

(52) U.S. Cl. 257/68

(57) ABSTRACT

In a capacitor having a semiconductor-insulator-metal (SIM) structure, an upper electrode may be formed into a multilayer structure including a polycrystalline semiconductor Group IV material. A dielectric layer may include a metal oxide, and a lower electrode may include a metal-based material. Therefore, a capacitor may have a sufficiently small equivalent oxide thickness (EOT) and/or may have improved current leakage characteristics.

### PRIORITY STATEMENT

This application claims priority under 35 USC § 119 to Korean Patent Application No. 2005-45383, filed on May 30, 2005, in the Korean Intellectual Property Office (KIPO), the entire contents of which are herein incorporated by reference.

### BACKGROUND

1. Field

Example embodiments of the present invention relate to a capacitor, for example, a capacitor having a semiconductor-insulator-metal (SIM) structure including an upper electrode having a multilayer structure that includes a polycrystalline semiconductor Group IV material, a dielectric layer and a lower electrode of the capacitor, and methods of manufacturing a capacitor, for example, methods of manufacturing a capacitor having a SIM structure.

2. Description of the Related Art

A dynamic random-access memory (DRAM) device may include an access transistor and a storage capacitor as a unit cell. A capacitor may have to be small in order to satisfy requirements such as an increase of an integration degree. A great deal of importance has been placed on a method of reducing a size and increasing a capacitance of a capacitor in a manufacturing process for a semiconductor device, having a higher degree of integration. For example, a method of increasing a capacitance without enlarging a horizontal area of a capacitor has been intensively studied so as to satisfy the above requirement of a higher integration degree of a semiconductor device.

A storage capacitance of a capacitor may be represented as the following well-known equation (1).
C=ε0εA/D (1)

In equation (1), “ε0” and “ε” denote an absolute dielectric constant and a relative dielectric constant of a dielectric layer, respectively, and “A” denotes an effective area of a lower electrode. “D” denotes a thickness of a dielectric layer.

Referring to equation (1), a capacitance of a capacitor may be increased as an effective area A of a lower electrode may be enlarged, as a thickness D of a dielectric layer may be decreased, and as dielectric constants ε0 and ε of a dielectric layer may be increased. Particularly, when a dielectric layer of a capacitor comprises a material of a higher dielectric constant, there may be advantages in that an equivalent oxide thickness (EOT) of a dielectric layer may be sufficiently small, and a current leakage may be also sufficiently reduced between upper and lower electrodes of a capacitor. For the above reasons, a dielectric layer of a recent capacitor may comprise a material of a higher dielectric constant. Examples of a material of a higher dielectric constant include tantalum oxide, aluminum oxide, zirconium oxide, hafnium oxide, titanium oxide, and/or the like.

However, when a capacitor may be formed into a metal-insulator-semiconductor (MIS) structure including an upper electrode, a dielectric layer and a lower electrode, respectively, a dielectric layer may be difficult to form at an EOT below about 25 Å, although a dielectric layer comprises a material of a higher dielectric constant, since metal of an upper electrode depletes away the material of a higher dielectric constant of a dielectric layer during the formation process of a MIS-structured capacitor.

For example, when a MIS-structured capacitor includes an upper electrode comprising a mixture of titanium nitride and polysilicon and/or the like, a dielectric layer comprising a mixture of aluminum oxide and hafnium oxide and/or the like, and a lower electrode comprising polysilicon and/or the like, a dielectric layer may be practically formed to an EOT of about 28 Ådespite a required EOT of about 24 Å. In addition, there is a problem in that a MIS-structured capacitor may be formed on a substrate through a much more complicated process, because of additional processes such as a hemispherical glass (HSG) process and a nitrification process. The HSG process enlarges the effective area of a lower electrode of a capacitor, and a surface of a dielectric layer may be sufficiently nitrified through the nitrification process. For the above reasons, a recent capacitor may be formed into a metal-insulator-metal (MIM) structure including an upper electrode, a dielectric layer and a lower electrode, respectively. A conventional MIM-structured capacitor may include a lower electrode comprising titanium nitride, a dielectric layer comprising aluminum oxide, and an upper electrode comprising a mixture of titanium nitride and polycrystalline silicon germanium.

A storage capacitance of a MIM-structured capacitor may be much greater than that of a MIS-structured capacitor. However, a MIM-structured capacitor still may have the above problem in that metal of an upper electrode depletes away the material of a higher dielectric constant of a dielectric layer during the formation process of a MIM-structured capacitor, so that a dielectric layer in a MIM-structured capacitor may be difficult to form to a sufficiently small EOT. Moreover, a MIM-structured capacitor may have a disadvantage with respect to current leakage.

A conventional SIM-structured capacitor may have a lower electrode comprising titanium nitride, a dielectric layer comprising aluminum oxide, and an upper electrode comprising polycrystalline silicon.

A SIM-structured capacitor may have a sufficiently reduced EOT of a dielectric layer due to the polycrystalline silicon germanium of an upper electrode. However, a SIM-structured capacitance still may have disadvantages with respect to storage capacitance and the current leakage.

### SUMMARY

Example embodiments of the present invention may provide a capacitor having a smaller equivalent oxide thickness (EOT) and/or improved current leakage characteristics.

Example embodiments of the present invention may provide a method of forming the above capacitor.

According to an example embodiment of the present invention, there may be provided a capacitor wherein a lower electrode may be positioned on a semiconductor substrate, and a dielectric layer may be positioned on the lower electrode. An upper electrode may be positioned on the dielectric layer, and the upper electrode may have a multilayer structure including a polycrystalline semiconductor Group IV material.

In an example embodiment of the present invention, the polycrystalline semiconductor Group IV material may include silicon, germanium, a combination thereof, and/or the like.

In an example embodiment of the present invention, the multilayer structure of the upper electrode may include one of a first combination of a first layer comprising silicon and/or the like, and a second layer comprising silicon germanium, and/or the like; a second combination of a first layer comprising germanium and/or the like, and a second layer comprising silicon germanium and/or the like; a third combination of a first layer comprising silicon germanium and/or the like, and a second layer comprising silicon and/or the like; and a fourth combination of a first layer comprising silicon germanium and/or the like and a second layer comprising germanium and/or the like. An atomic ratio of germanium with respect to silicon in the silicon germanium may range from about 0.0001 to about 10,000. An upper electrode may be formed at a temperature of about 400° C. to about 500° C. An upper electrode may further comprise a Group III or Group V semiconductor material.

According to another example embodiment of the present invention, there may be provided a method of forming a capacitor. A lower electrode may be formed on a semiconductor substrate. A dielectric layer may be formed on the lower electrode. An upper electrode may be formed on the dielectric layer into a multilayer structure including a polycrystalline semiconductor Group IV material.

In an example embodiment of the present invention, the polycrystalline semiconductor Group IV material may include silicon, germanium and silicon germanium and/or the like. The multilayer structure of the upper electrode may include one of a first combination of a first layer comprising silicon and/or the like, and a second layer comprising silicon germanium and/or the like; a second combination of a first layer comprising germanium and/or the like, and a second layer comprising silicon germanium and/or the like; a third combination of a first layer comprising silicon germanium and/or the like, and a second layer comprising silicon and/or the like; and a fourth combination of a first layer comprising silicon germanium and/or the like, and a second layer comprising germanium and/or the like. An atomic ratio of germanium with respect to silicon may range from about 0.0001 to about 10,000. An upper electrode may be formed at a temperature of about 400° C. to about 500° C. A Group III or Group V semiconductor material may be further doped onto an upper electrode comprising a polycrystalline semiconductor Group IV material.

According to another example embodiment of the present invention, there may be provided a method of forming a capacitor. In the method of manufacturing a capacitor, an insulation layer pattern having an opening may be formed on a semiconductor substrate, and a lower electrode layer may be continuously formed on a sidewall and a bottom of the opening, and a top surface of the insulation layer pattern, the lower electrode layer comprising metal. A sacrificial layer may be formed on a substrate including a lower electrode layer to a sufficient thickness to fill up the opening. A sacrificial layer may be partially removed from a substrate until the top surface of an insulation layer pattern is exposed, so that a sacrificial layer remains only in the opening. The remaining sacrificial layer and the insulation layer pattern may be removed from a substrate to thereby form a cylindrical lower electrode on a substrate. A dielectric layer may be formed on a lower electrode. A dielectric layer may comprise metal oxide. An upper electrode may be formed into a multilayer structure on a dielectric layer, and the multilayer structure may include a first layer comprising a first polycrystalline semiconductor Group IV material and a second layer comprising the first polycrystalline semiconductor Group IV material and a second polycrystalline semiconductor Group IV material. The first polycrystalline semiconductor Group IV material may be different from the second polycrystalline semiconductor Group IV material.

In an example embodiment of the present invention, the lower electrode layer may comprise one of titanium, titanium nitride and/or the like. The sacrificial layer may include one of an oxide layer and a photoresist layer. The dielectric layer may comprise hafnium oxide, aluminum oxide, a combination thereof, and/or the like. The first semiconductor material may include one of silicon, germanium and/or the like, and the second semiconductor material may include silicon germanium and/or the like, and an atomic ratio of germanium with respect to silicon in the silicon germanium may range from about 0.0001 to about 10,000. The second semiconductor material may include one of silicon, germanium and/or the like, and the first semiconductor material may include silicon germanium and/or the like, and an atomic ratio of germanium with respect to silicon in the silicon germanium may range from about 0.0001 to about 10,000. The first and second layers may be formed at a temperature of about 400° C. to about 500° C.

In an example embodiment of the present invention, a Group III or Group V semiconductor material may be further doped onto the first layer of the multilayer structure, and a Group III or Group V semiconductor material may be also doped onto the second layer of the multilayer structure.

According to example embodiments of the present invention, an upper electrode of a capacitor may have a multilayer structure including a polycrystalline semiconductor Group IV material. The upper electrode does not deplete a dielectric layer so that a sufficient equivalent oxide thickness may be ensured. Additionally, the upper electrode may have the multilayer structure so that a capacitor may have an advantage with respect to current leakage.

### BRIEF DESCRIPTION OF THE DRAWINGS

The above and other features and advantages of example embodiments of the present invention will become more apparent by describing in detailed example embodiments thereof with reference to the accompanying drawings, in which:

FIG. 1 illustrates a capacitor in accordance with an example embodiment of the present invention;

FIGS. 2A to 2J illustrate processing steps for a method of forming a cylindrical capacitor in accordance with an example embodiment of the present invention;

FIG. 3 is a graph illustrating a measured storage capacitance of various test capacitors; and

FIG. 4 is a graph illustrating a leakage current measured from various test capacitors.

### DETAILED DESCRIPTION OF THE EXAMPLE EMBODIMENTS OF THE PRESENT INVENTION

Various example embodiments of the present invention will now be described more fully with reference to the accompanying drawings, in which some example embodiments of the present invention are shown. Example embodiments of the present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of the example embodiments of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

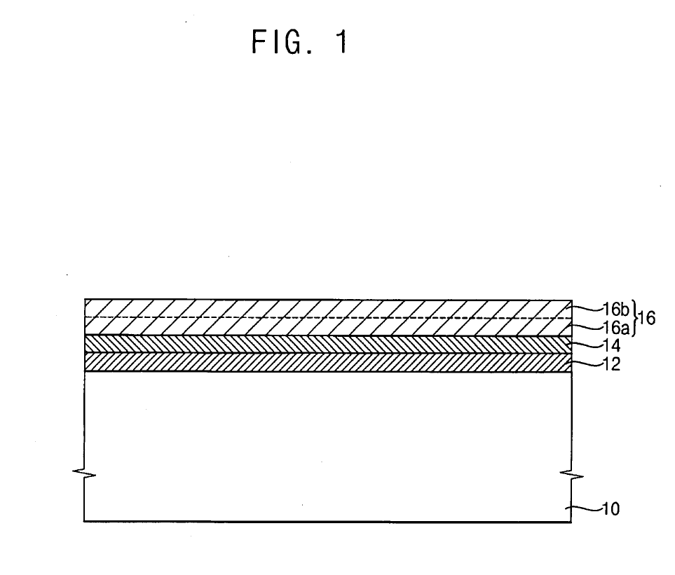

FIG. 1 illustrates a capacitor in accordance with an example embodiment of the present invention.

Referring to FIG. 1, a capacitor may include a lower electrode 12, a dielectric layer 14, and an upper electrode 16 that are sequentially stacked on a semiconductor substrate 10.

The lower electrode 12 may comprise a material including metal and/or the like. For example, the lower electrode 12 may include a metal nitride and/or the like, so that a capacitance is larger than that of a capacitor of which a lower electrode includes polysilicon and/or the like. For example, the material including metal of the lower electrode 12 may include titanium, titanium nitride, tantalum, tantalum nitride, ruthenium (Ru), tungsten, tungsten nitride, platinum (Pt), ruthenium oxide (RuO₂), strontium ruthenium oxide (SrRuO₃) and/or the like. In an example embodiment of the present invention, the lower electrode 12 may include titanium nitride.

The dielectric layer 14 includes a metal oxide and a metal oxynitride, so that an EOT of the dielectric layer 14 may be much smaller and a dielectric constant of the dielectric layer 14 may be much larger than when the dielectric layer 14 includes an oxide. Examples of the metal oxide or the metal oxynitride may be aluminum oxide (AlO₃), hafnium oxide (HfO₂), tantalum oxide (Ta₂O₅), zirconium oxide (ZrO₂), hafnium silicon oxide (HfSiO₂), zirconium silicon oxide (ZrSiO), titanium oxide (TiO₂), lanthanum oxide (LaO), lead titanium oxide (PbTiO₃), lead zirconium titanium oxide [Pb(Zr,Ti)O₃], strontium titanium oxide (SrTiO₃), barium strontium titanium oxide [(Ba,Sr)TiO₃], aluminum oxynitride, hafnium oxynitride, tantalum oxynitride, zirconium oxynitride, hafnium silicon oxynitride, zirconium silicon oxynitride, titanium oxynitride, lanthanum oxynitride and/or the like. In an example embodiment of the present invention, the dielectric layer 14 may include a multilayer of hafnium oxide and aluminum oxide and/or the like.

In an example embodiment of the present invention, the upper electrode 16 includes a polycrystalline semiconductor Group IV material, so that the dielectric layer 14 may not be depleted away from the substrate 10 to thereby reduce the EOT thereof. In addition, the upper electrode 16 may have a multilayer structure, to thereby improve current leakage characteristics of the capacitor. Examples of the polycrystalline semiconductor Group IV material include silicon and germanium and/or the like, and the multilayer structure includes first and second layers 16a and 16b on the dielectric layer 14. As a result, the multilayer structure of the upper electrode 16 may have various combinations of the first and second layers 16a and 16b based on the silicon and germanium as such: a first example multilayer structure including the first layer 16a including silicon and/or the like, and the second layer 16b including silicon germanium and/or the like; a second example multilayer structure including the first layer 16a comprising germanium and/or the like, and the second layer 16b including silicon germanium and/or the like; a third example multilayer structure including the first layer 16a including silicon germanium and/or the like, and the second layer 16b including silicon and/or the like; and a fourth example multilayer structure including the first layer 16a comprising silicon germanium and/or the like, and the second layer 16b including germanium and/or the like. In an example embodiment of the present invention, the upper electrode 16 may have the third multilayer structure including the first layer 16a including silicon germanium and/or the like, and the second layer 16b comprising silicon and/or the like.

An atomic ratio of germanium with respect to silicon in silicon germanium of the first layer 16a may be in a range of about 0.0001 to about 10,000. In an example embodiment of the present invention, an atomic ratio of germanium with respect to silicon may be in a range of about 0.01 to about 100, for example, a range of about 0.1 to about 10. In an example embodiment of the present invention, an atomic ratio of germanium with respect to silicon in silicon germanium may be about 1.0.

Group III or Group V semiconductor materials may be doped into the upper electrode 16 including a polycrystalline semiconductor Group IV material, thereby improving electrical controllability of the upper electrode 16. An example of the Group III semiconductor material includes boron (B), and examples of the Group V semiconductor material include phosphorus (P), arsenic (As), and/or the like. In an example embodiment of the present invention, phosphorous (P) may be doped into the upper electrode 16.

The upper electrode 16 may be formed on the dielectric layer 14 by a low-pressure chemical vapor deposition (LPCVD) process. In an example embodiment of the present invention, the LPCVD process may be performed at a temperature of about 400° C. to about 500° C., for example, about 400° C. to about 470° C., so that the upper electrode 16 may be formed on the dielectric layer 14 under a relatively low temperature below about 500° C. As a result, thermal damage to the dielectric layer 14 and the current leakage from the dielectric layer 14 may be sufficiently reduced. In addition, the LPCVD process may be performed under a pressure of about 0.2 Torr to about 1.0 Torr, for example, about 0.3 Torr to about 0.5 Torr.

As mentioned above, the capacitor of an example embodiment of the present invention may have a structure including a multilayer including a polycrystalline semiconductor Group IV material as the upper electrode 16, a metal oxide of a higher dielectric constant as the dielectric layer 14 and a metal nitride as the lower electrode 12. That is, the capacitor of an example embodiment of the present invention may have a semiconductor-insulator-metal (SIM) structure including the upper electrode 16 that may be formed as a multilayer structure. In particular, the upper electrode 16 may have a multilayer structure including a polycrystalline semiconductor Group IV material, so that an EOT of the dielectric layer 14 of the capacitor may be smaller and/or the current leakage from the dielectric layer 14 may be reduced.

The capacitor of an example embodiment of the present invention may be produced by sequentially forming the lower electrode 12, the dielectric layer 14, and the upper electrode 16 on the semiconductor substrate 10.

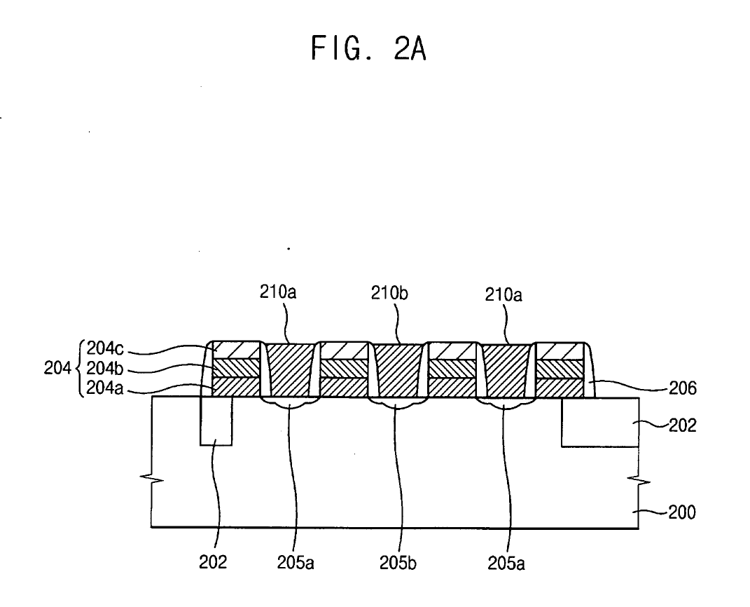

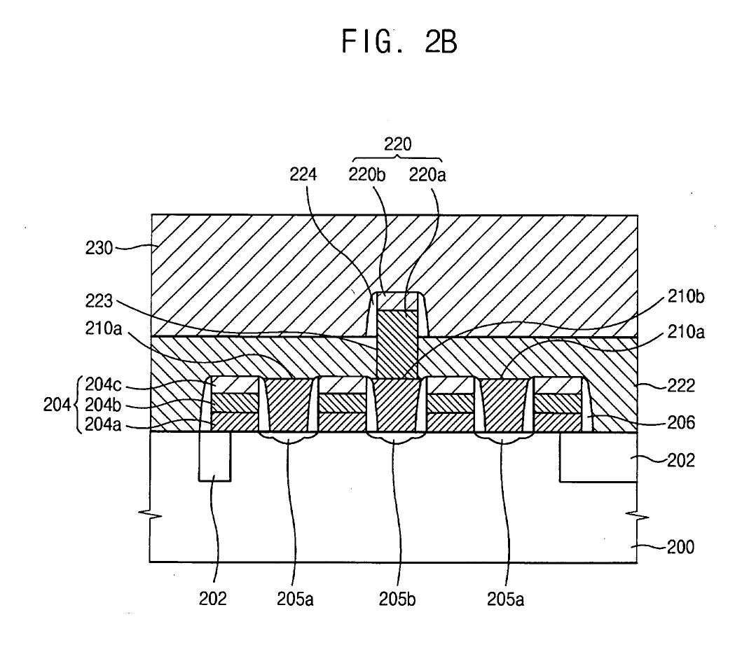

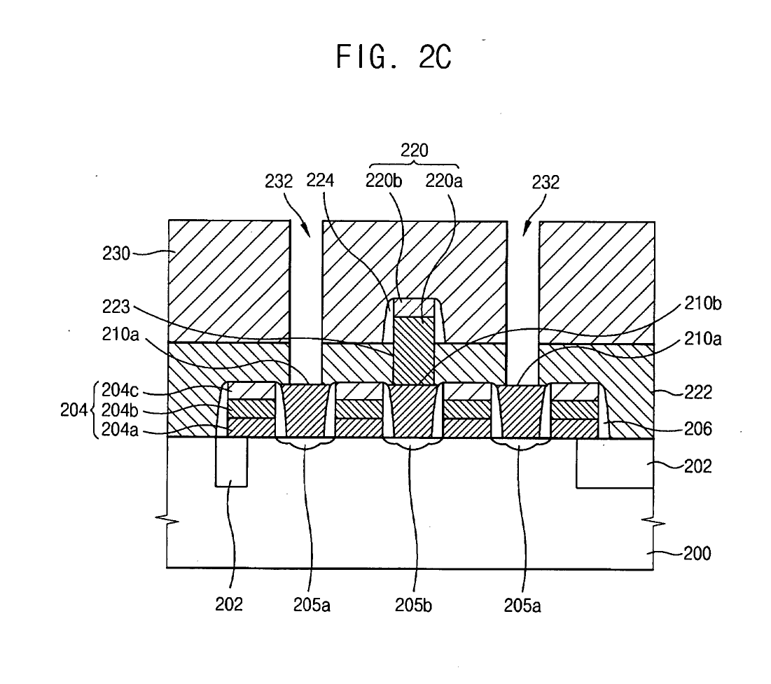

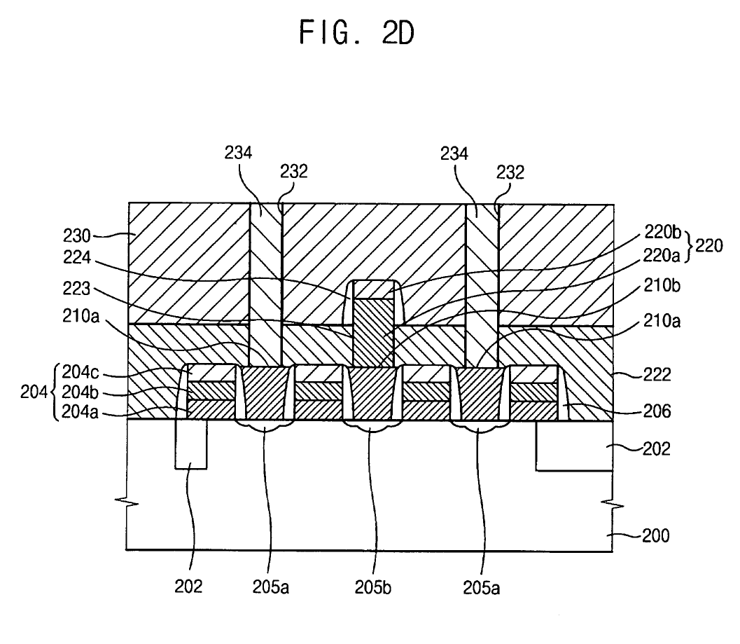

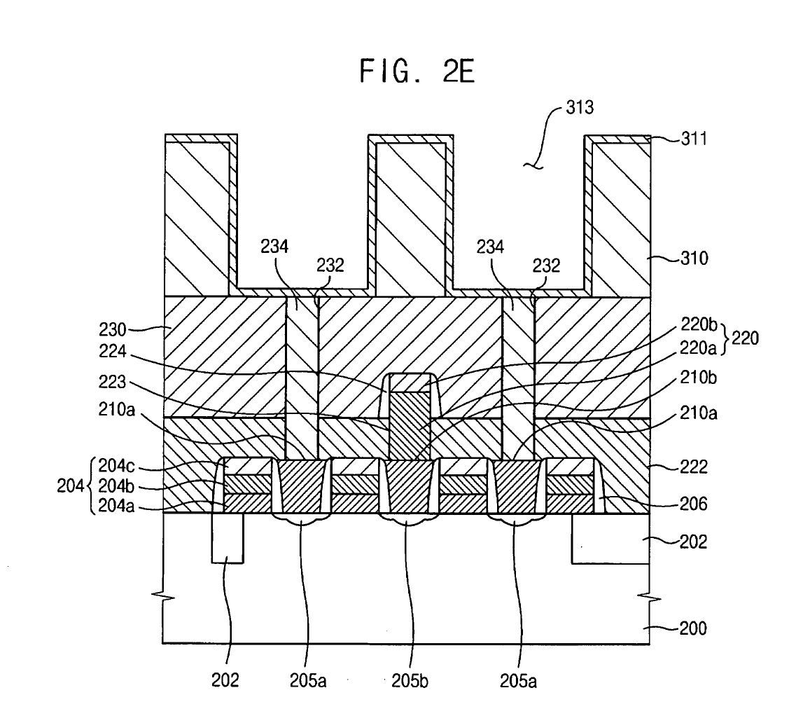

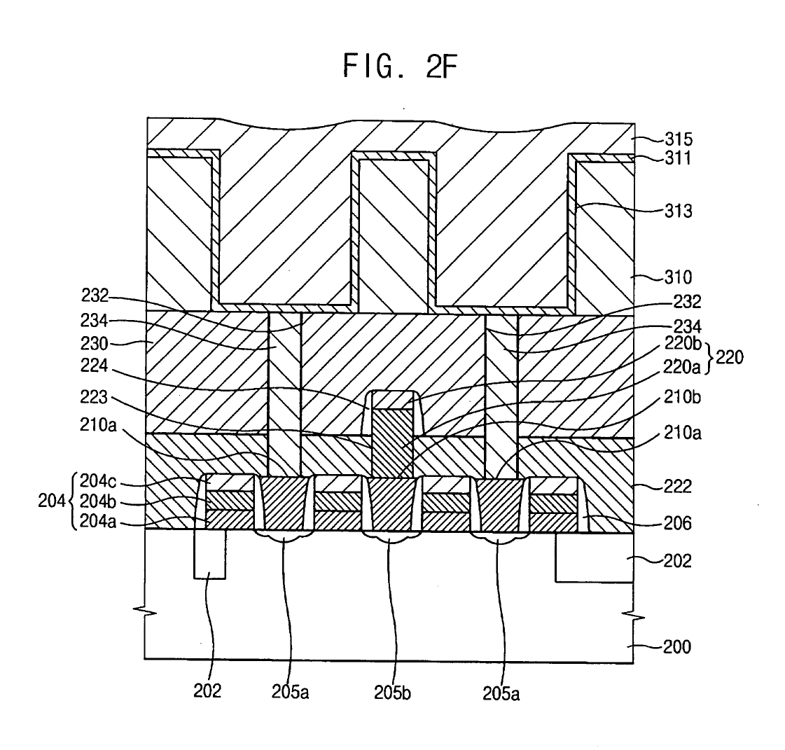

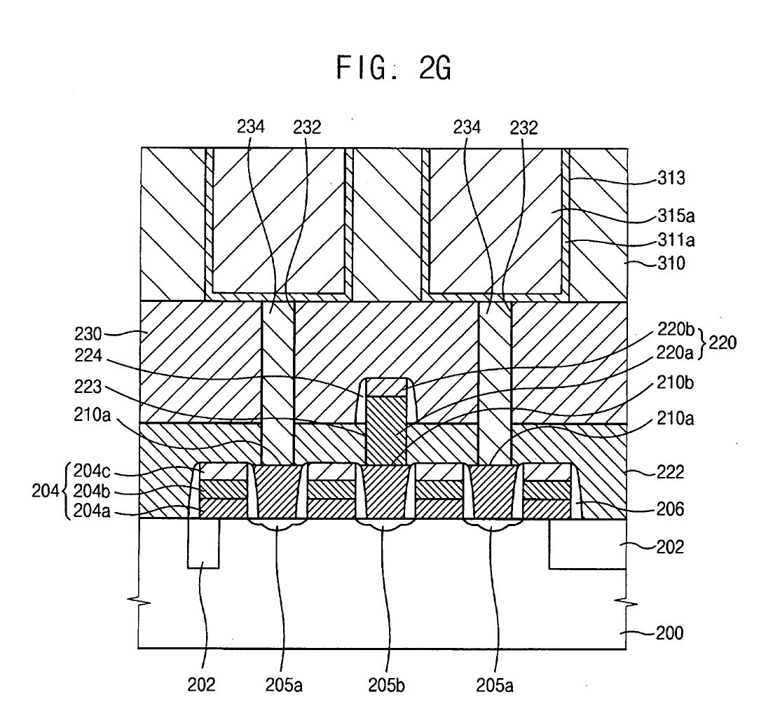

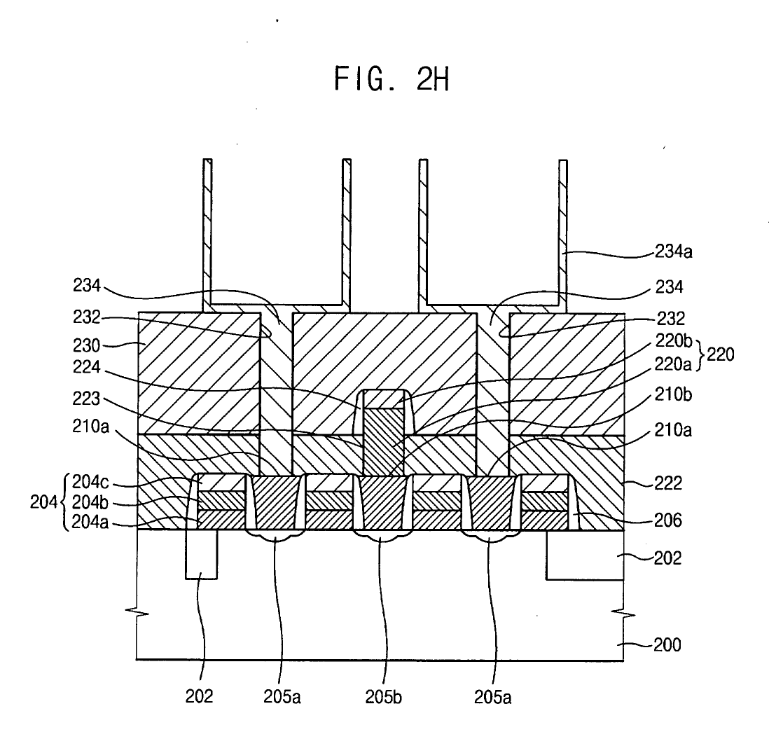

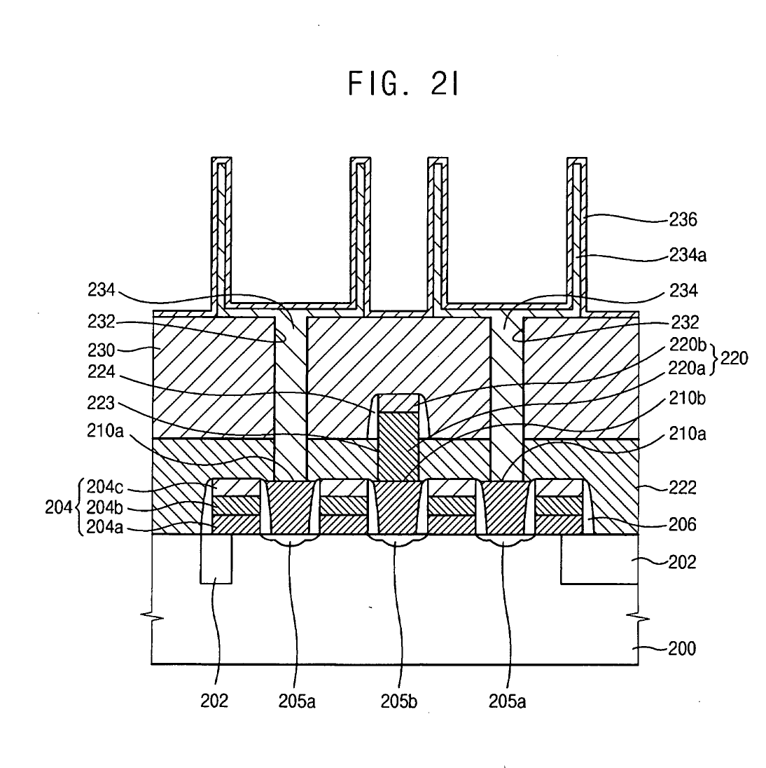

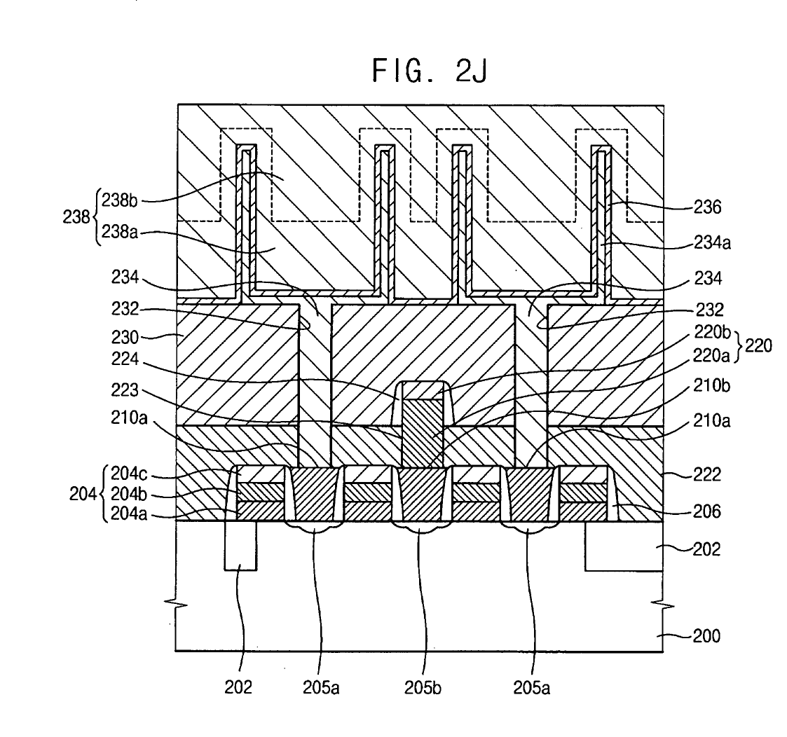

Hereinafter, a method of forming a cylindrical capacitor will be described in detail with reference to FIGS. 2A to 2J in accordance with the above-described method of forming a SIM-structured capacitor.

FIGS. 2A to 2J illustrate processing for a method of forming a cylindrical capacitor in accordance with an example embodiment of the present invention.

Referring to FIG. 2A, a trench isolation layer 202 may be formed on a semiconductor substrate 200 by an isolation process. The substrate 200 may be partially removed by an etching process, so that a trench may be formed to a desired depth on a top surface of the substrate 200. An active region of the substrate 200 on which various conductive structures may be formed is defined by the trench. A thin layer including an insulation material of an improved gap-fill characteristic, such as an oxide, may be formed on the semiconductor substrate 200 to a sufficient thickness to fill the trench. The insulation thin layer may be partially removed by a planarization process until the top surface of the substrate 200 is exposed, so that the insulation thin layer may remain only in the trench. The conductive structures on the active region may be electrically isolated from each other by the insulation thin layer in the trench, so that the insulation thin layer in the trench may be referred to as a device isolation layer. The device isolation layer of an example embodiment of the present invention may be referred to as the trench isolation layer 202. In an example embodiment of the present invention, a pad oxide layer and a pad nitride layer may be further formed after the trench isolation layer 202 is formed in the trench, and a liner may be further formed on a sidewall and a bottom surface of the trench.

The trench isolation layer 202 may be electrically inactive and defines the active region of the substrate 200. Thus, a portion of the substrate 200 corresponding to the trench isolation layer 202 may be referred to as an inactive region of the substrate 200, and may be also widely known as a field region of the substrate 200. That is, the substrate 200 may be divided into the active region and the inactive region by the trench isolation layer 202 in the trench. While an example embodiment of the present invention discloses a trench isolation layer as the device isolation layer, a field oxide layer may also be utilized in place of or in conjunction with the trench isolation layer, as would be known to one of ordinary skill in the art.

A first insulation layer (not shown), a conductive layer (not shown) and a second insulation layer (not shown) may be sequentially formed on the substrate 200, and the second insulation layer, the conductive layer and the first insulation layer may be sequentially and partially removed from the substrate 200 to thereby form a gate pattern 204 on the substrate 200. The gate pattern 204 may include a gate insulation layer 204a, a gate conductive layer 204b and a hard mask layer 204c that may be sequentially stacked on the active region of the substrate 200. In an example embodiment of the present invention, the gate insulation layer 204a may include an oxide and/or the like, and the gate conductive layer 204b may include polysilicon and tungsten suicide and/or the like. The hard mask layer 204c may include a nitride and/or the like. For example, The gate insulation layer 204a may include a metal oxide capable of reducing an equivalent oxide thickness, and the gate conductive layer 204b may be formed into a multilayer in which tungsten silicide and polysilicon and/or the like, heavily doped with impurities, may be sequentially stacked on the gate insulation layer 204a. The hard mask layer 204c may be omitted in some cases.

A first spacer 206, including a nitride, may be formed on both sidewalls of the gate pattern 204.

Impurities may be more heavily implanted onto a top surface of the substrate 200 using the gate pattern 204 and the first spacer 206 as an implantation mask, so that source/drain regions 205a and 205b may be formed at surface portions of the substrate 200 adjacent to the gate pattern 204. In an example embodiment of the present invention, impurities may be more lightly implanted onto the top surface of the substrate 200 using the gate pattern 204 as an implantation mask before the first spacer 206 may be formed on the sidewall of the gate spacer 204, so that the source/drain regions 205a and 205b may include a lightly doped source/drain (LDD) structure.

A transistor, including the gate pattern 204 and the source/drain regions 205a and 205b, may be formed on a surface of the active region of the substrate 200. One of the source/drain regions 205a and 205b may be a capacitor contact area electrically connected to a lower electrode (not shown) of a capacitor, and the other may be a bit line contact area electrically connected to a bit line (not shown). In an example embodiment of the present invention, a source region 205a makes electrical contact with the capacitor, and a drain region 205b makes electrical contact with the bit line.

A conductive layer (not shown) may be formed on the substrate 200 including the gate pattern 204 to a sufficient thickness to fill a gap between gate patterns 204, and may be removed from the substrate 200 by a planarization process until a top surface of the gate pattern 204 may be exposed. As a result, the conductive layer may remain in the gap between the gate patterns 204, to thereby form a capacitor contact pad 210a making electrical contact with the source region 205a and a lower electrode of a capacitor, and a bit line pad 210b making electrical contact with the drain region 205b and a bit line. In an example embodiment of the present invention, the conductive layer may include polysilicon and/or the like, and the planarization process may include a chemical mechanical polishing (CMP) process and an etch-back process using an etching rate difference between the conductive layer and the hard mask layer 204c. As a result, the capacitor contact pad 210a may be formed on the top surface of the substrate 200 corresponding to the capacitor contact area, and the bit line contact pad 210b may be formed on the top surface of the substrate 200 corresponding to the bit line contact area.

Referring to FIG. 2B, a bit line structure 220 may be formed on the bit line contact pad 210b, to thereby make electrical contact with the bit line contact pad 210b. For example, a first insulating interlayer 222 including an insulation material such as an oxide may be formed on the substrate 200 including the gate pattern 204, the capacitor contact pad 210a and the bit line contact pad 210b to a sufficient thickness to cover the gate pattern 204 and the pads 210a and 210b. The first insulating interlayer 222 may be partially removed from the substrate 200. The first insulating interlayer 222 may be partially removed from the substrate 200 through a photolithography process to thereby form a first opening 223 through which the bit line contact pad 210b may be exposed. A metal layer (not shown) including tungsten may be formed on the first insulating interlayer 222 to a sufficient thickness to fill the first opening 223 and may be planarized by a planarization process until a top surface of the first insulating interlayer 222 may be exposed. The metal layer may remain only in the first opening 223 and a top surface of the metal layer may be coplanar with a top surface of the first insulating interlayer 222. An insulation layer (not shown), including a nitride and/or the like, may be formed on the metal layer and the first insulating interlayer 222, and the insulation layer and the metal layer may be sequentially removed from the substrate 200 to thereby form a metal layer pattern 220a and an insulation layer pattern 220b on the metal layer pattern 220a. The metal layer pattern 220a may function as a bit line for a semiconductor device, and the metal layer pattern 220a and the insulation layer pattern 220b may be altogether referred to as the bit line structure 220 hereinafter. Although an example embodiment of the present invention discloses the metal layer pattern 220a including tungsten as the bit line, any other conductive material may also be utilized as the bit line in place of the metal layer pattern 220a, as would be known to one of ordinary skill in the art.

A second spacer 224 may be formed on both sidewalls of the bit line structure 220. The second spacer 224 may include nitride and/or the like. A second insulating interlayer 230 may be formed on the bit line structure 220, the second spacer 224, and the first insulating interlayer 222.

Referring to FIG. 2C, the second insulating interlayer 230 and the first insulating interlayer 222 may be sequentially removed from the substrate 200 by an etching process to thereby form a second opening 232 through which the capacitor contact pad 210a may be exposed. An etching rate of the nitride of the second spacer 224 may be different from that of the oxide of the first and second insulating interlayers 222 and 230 in an etching process, so that the second opening 232 may be formed across the first and second insulating interlayers 222 and 230 during the above etching process due to the etching rate difference between the nitride and the oxide.

Referring to FIG. 2D, a contact plug 234 that is to be connected to a lower electrode of a capacitor may be formed in the second opening 232. A conductive layer may be formed on the second insulating interlayer 230 to a sufficient thickness to fill the second opening 232, and may be planarized by a planarization process until a top surface of the second insulating interlayer 230 may be exposed. As a result, a conductive layer may remain only in the second opening 232 to thereby form the contact plug 234 making contact with the capacitor contact pad 210a in the second opening 232. The conductive layer for the contact plug 234 may include polycrystalline silicon, metal, metal nitride and/or the like.

A cylindrical lower electrode 234a may be formed on the second insulating interlayer 230 and may be electrically connected to the contact plug 234, as will be described as follows with reference to FIGS. 2E to 2H.

Referring to FIG. 2E, a third insulating interlayer (not shown) may be formed on the second insulating interlayer 230 and the contact plug 234, and may be partially removed from the second insulating interlayer 230 to thereby form a third insulating interlayer pattern 310 having a third opening 313 through which the contact plug 234 may be exposed. A thin layer 311 for a lower electrode may be continuously formed on a sidewall and a bottom of the third opening 313 and a top surface of the third insulating interlayer pattern 310.

The thin layer 311 for the lower electrode may include a metal or a metal nitride. In an example embodiment of the present invention, the thin layer 311 for the lower electrode may include a titanium nitride layer formed through a chemical vapor deposition (CVD) process. For example, the CVD process may be performed at a temperature below about 550° C. using titanium tetrachloride (TiCl₄) gas and ammonia (NH₃) gas as a source gas to thereby form the thin layer 311 including titanium nitride.

Besides the CVD process, the thin layer 311 including titanium nitride may also be formed by an atomic layer deposition (ALD) process or a sputtering process. However, the ALD process may have a disadvantage of a low throughput, and the sputtering process may have a disadvantage of poor step coverage.

Referring to FIG. 2F, a sacrificial layer 315 may be formed on the thin layer 311 to a sufficient thickness to fill up the third opening 313. Hence, the third opening 313 may be sufficiently filled with the sacrificial layer 315. The sacrificial layer 315 may include an oxide layer or a photoresist film. In an example embodiment of the present invention, the sacrificial layer 315 includes a photoresist film.

The sacrificial layer 315 may be planarized by a planarization process until a top surface of the thin layer 311 may be exposed. The planarization process may include an etching process against a whole surface of the sacrificial layer 315. The thin film 311 on a top surface of the third insulating interlayer pattern 310 may be removed from the third insulating interlayer pattern 310.

As a result, the thin layer 311 may remain only on the sidewall and bottom of the third opening 313, and the sacrificial layer 315 may remain only in the third opening 313, as shown in FIG. 2G. Hereinafter, a residual thin layer on the sidewall and bottom of the third opening 313 may be designated as reference numeral 311a, and the residual sacrificial layer in the third opening 313 may be designated as reference numeral 315a, respectively. The residual sacrificial layer 315a may be removed from the residual thin layer 311a, and the third insulating interlayer pattern 310 may be removed from the second insulating interlayer 230. The third insulating interlayer pattern 310 may be removed from the second insulating interlayer 230 before the residual sacrificial layer 315a may be removed from the residual thin layer 311a, as would be known to one of ordinary skill in the art.

That is, the residual thin layer 311a may be formed into a cylindrical lower electrode 234a separated from each other by each node as a result of the removal of the residual sacrificial layer 315a and the third insulating interlayer 310, as shown in FIG. 2H.

Referring to FIG. 2I, a dielectric layer 236 may be formed on the lower electrode 234a and the second insulating interlayer 230. The dielectric layer 236 may include a metal oxide, a metal oxynitride, and/or the like, capable of reducing an equivalent oxide thickness of the dielectric layer 236. In an example embodiment of the present invention, the dielectric layer 236 may include hafnium oxide and aluminum oxide and/or the like. In an example embodiment of the present invention, the dielectric layer 236 may be formed by an ALD process. In the ALD process, controlling a thickness of the dielectric layer 236 may be easier than that in a CVD process. Thus, the dielectric layer 236 may be formed by the ALD process.

Hereinafter, a method of forming the dielectric layer 236 including a hafnium oxide layer and an aluminum oxide layer by an ALD process will be illustrated.

A reaction chamber for the ALD process may be set under an desired processing temperature and pressure. When the processing temperature is below about 200° C., a reaction velocity of reaction materials tends to be negligible in the ALD process, which may reduce productivity, and when the processing temperature is over about 400° C., a dielectric layer tends to be crystallized and CVD characteristics may occur in the dielectric layer despite the performing of the ALD process. Accordingly, although the ALD process according to example embodiments of the present invention may be operated at other temperatures, the reaction chamber for the ALD process may be maintained at a temperature between about 200° C. and about 400° C. In addition, when the processing pressure is below about 0.1 Torr, a reaction velocity of the reaction materials also tends to be negligible in the ALD process, and when the processing pressure is over about 0.3 Torr, the reaction velocity of the reaction materials may be so high that the final thickness of the dielectric layer may be difficult to accurately control. Accordingly, although the ALD process according to example embodiments of the present invention may be operated at other pressures, the reaction chamber for the ALD process may be maintained at a pressure between about 0.1 Torr and about 0.3 Torr.

The semiconductor device 200 may be positioned in the reaction chamber under the above-mentioned temperature and pressure, and the reaction materials may be provided into the reaction chamber for the ALD process. For example, a hafnium precursor such as tetrakis ethyl methyl amino hafnium (TEMAH, Hf[NC₂H₅CH₃]₄), hafnium t-butoxide (Hf(OtBu)₄), and/or the like may be provided into the reaction chamber as the reaction material for about 0.5 seconds to about 3 seconds. In an example embodiment of the present invention, the reaction material may pass through a bubbler, so that a gaseous material may be provided into the reaction chamber as the reaction material. Some of the reaction materials may be chemisorbed onto a surface of a substrate 200, and the remaining portion of the reaction materials may be physisorbed to the chemisorbed reaction material or drift around the semiconductor substrate 200.

A first purge gas, e.g., argon gas, may be provided onto the substrate 200 for about 0.5 seconds to about 20 seconds. The physisorbed reaction material or the drifted reaction material may be removed from the reaction chamber, and the chemisorbed reaction material may only remain on the substrate 200. That is, the chemisorbed hafnium precursor may only remain on the substrate 200.

An oxidizer such as ozone (O₃), oxygen (O₂), water vapor (H₂O), plasma oxygen, remote plasma oxygen and/or the like may be provided onto the substrate 200 including the hafnium precursor for about 1 second to about 7 seconds. As a result, the chemisorbed hafnium precursor may be chemically reacted with the oxidizer to thereby oxidize the hafnium precursor.

A second purge gas may be provided onto the substrate 200 in the same method as described above, so that the residual oxidizer that may not be chemically reacted with the chemisorbed hafnium precursor may be removed from the reaction chamber. Consequently, a solid material layer comprising hafnium oxide (HfO₂) may be formed on the substrate 200.

The above unit processing of providing reaction materials, providing the first purge gas, providing the oxidizer and providing the second purge gas may be sequentially repeated at least once, so that a hafnium oxide layer may be formed on the substrate 200 to a desired thickness through the ALD process.

An aluminum oxide layer may be formed on the hafnium oxide layer. The processing for forming the aluminum oxide layer may be the same as those for forming the hafnium oxide layer except that an aluminum precursor such as trimethyl aluminum (TMA, Al(CH₃)₃) and/or the like may be utilized as the reaction material in place of the hafnium precursor.

As mentioned above, the dielectric layer 236 may be formed into a double layer structure having the hafnium oxide layer and the aluminum oxide layer and/or the like that may be sequentially stacked on the substrate 200 by the ALD process. When a SIM-structured capacitor of example embodiments of the present invention including the double layer structure having the hafnium oxide layer and the aluminum oxide layer and/or the like, an EOT of the dielectric layer 236 in the SIM-structured capacitor was about 22 Å. That is, the dielectric layer 236 of an example embodiment of the present invention may have a sufficiently small EOT and/or a sufficiently higher dielectric constant.

Referring to FIG. 2J, an upper electrode 238 may be formed on the dielectric layer 236. In an example embodiment of the present invention, the upper electrode 238 may be formed into a multilayer structure including polycrystalline semiconductor Group IV materials. Examples of the polycrystalline semiconductor Group IV materials include silicon and germanium, so that various combinations of silicon and germanium may be allowable in the multilayer structure of the upper electrode 238. In an example embodiment of the present invention, the multilayer structure of the upper electrode 238 includes a first layer 238a comprising silicon germanium, and a second layer 238b comprising silicon. Particularly, an atomic ratio of germanium with respect to silicon in silicon germanium may range from about 0.0001 to about 10,000. In an example embodiment of the present invention, an atomic ratio of germanium with respect to silicon in silicon germanium may be about 1.0. In addition, impurities such as Group III or Group V semiconductor materials may be further implanted onto the upper electrode 238 including the polycrystalline semiconductor Group IV materials. For example, phosphorous (P) may be further implanted onto the upper electrode 238. The upper electrode 238 may be formed on the dielectric layer 236 by a low-pressure CVD (LPCVD) process at a temperature of about 400° C. to about 500° C. and a pressure of about 0.2 Torr to about 1.0 Torr.

Hereinafter, detailed processing for forming the upper electrode 238 including a lower portion comprising silicon germanium and an upper portion comprising silicon by an LPCVD process will be described.

A processing chamber for the LPCVD process may be set under desired temperature and pressure. In an example embodiment of the present invention, the desired temperature and pressure may be set to be about 450° C. and about 0.4 Torr, respectively.

The semiconductor substrate 200 may be positioned in the processing chamber under the above desired temperature and pressure, and a silicon source gas and a germanium source gas may be provided into the processing chamber for the LPCVD process. The silicon source gas may include a silane-based gas such as a silane (SiH₄) gas and a disilane (SiH₆) gas, and the germanium source gas includes germanium tetrahydride (GeH₄) gas and germanium fluoride (GeF₄) gas. Hence, a silicon germanium layer may be formed on the dielectric layer 236 as the first layer 238a of the upper electrode 238. In an example embodiment of the present invention, an atomic ratio of silicon and germanium may be maintained to be about 1:1 during the formation of the silicon germanium layer by controlling a flow ratio of the silicon source gas and the germanium source gas. In addition, a phosphorous trihydride (PH₃) gas may be further provided onto the substrate 200 during the formation of the first layer 238a of the upper electrode 238, so that phosphorus (P) may be diffused into the first layer 238a of the upper electrode 238. In an example embodiment of the present invention, the first layer 238a may be transformed into a polycrystalline structure without any activation process to the first layer 238a.

The silicon source gas may be provided onto the first layer 238a of the upper electrode 238 in the same process as described above, so that the second layer 238b of the upper electrode 238 may be formed on the first layer 238a of the upper electrode 238. That is, the second layer 238b may be formed under the same temperature and pressure as for the first layer 238a. In addition, a phosphorous trihydride (PH₃) gas may be also provided onto the substrate 200 during the formation of the second layer 238b of the upper electrode 238, so that phosphorus (P) may be also diffused into the second layer 238b of the upper electrode 238. In an example embodiment of the present invention, the second layer 238b may also be transformed into a polycrystalline structure without any activation process to the second layer 238b. The second layer 238b may be formed in-situ with the first layer 238a.

Accordingly, the upper electrode 238 may include the first layer 238a comprising silicon germanium and the second layer 238b comprising silicon. That is, the upper electrode 238 may be formed into a multilayer structure comprising polycrystalline semiconductor Group IV materials, thereby improving structural stability of the upper electrode 238. As a result, a leakage current may be sufficiently reduced in a SIM-structured capacitor of an example embodiment of the present invention.

Evaluation of a Storage Capacitance

FIG. 3 is a graph illustrating a measured storage capacitance of various test capacitors.

In FIG. 3, test capacitors 1 to 4 may be comparative sample capacitors having the conventional MIS structure. The above MIS-structured comparative sample capacitor may include a lower electrode comprising polysilicon that may be formed into a hemi-spherical grain (HSG), a dielectric layer comprising hafnium oxide and aluminum oxide and an upper electrode comprising titanium nitride. Test capacitors 5 and 6 may be sample capacitors of an example embodiment of the present invention having the SIM structure. The above SIM-structured sample capacitor may include a lower electrode comprising titanium nitride and/or the like, a dielectric layer comprising hafnium oxide and aluminum oxide and/or the like, and an upper electrode having a multilayer structure. The multilayer structure of the upper electrode includes a first layer comprising silicon germanium and/or the like, and a second layer comprising silicon and/or the like. Test capacitors 7 to 12 may be comparative sample capacitors having the conventional MIM structure. The above MIM-structured comparative sample capacitor may include a lower electrode comprising titanium nitride, a dielectric layer comprising hafnium oxide and aluminum oxide and an upper electrode comprising titanium nitride. Test capacitors 13 to 15 may be comparative sample capacitors having the conventional SIM structure. The above conventional SIM-structured comparative sample capacitor may includes a lower electrode comprising titanium nitride and/or the like, a dielectric layer comprising hafnium oxide and aluminum oxide and/or the like and an upper electrode comprising silicon germanium and/or the like. Capacitances of each of the above test capacitors 1 to 15 were measured and were plotted onto the graph in accordance with each test capacitor, as shown in FIG. 3.

Referring to FIG. 3, the results of the capacitance measurements show that test capacitors 7 to 12 may have the greatest capacitance due to the MIM structure thereof.

Capacitances of the SIM-structured test capacitors 5 and 6 may be smaller than those of test capacitors 7 to 12, but may be greater than those of test capacitors 1 to 4 and test capacitors 13 to 15. Accordingly, the results of the capacitance measurement may indicate that the SIM structure of an example embodiment of the present invention contributes to capacitance improvement of a capacitor using the same.

Evaluation of a Current Leakage of a Capacitor

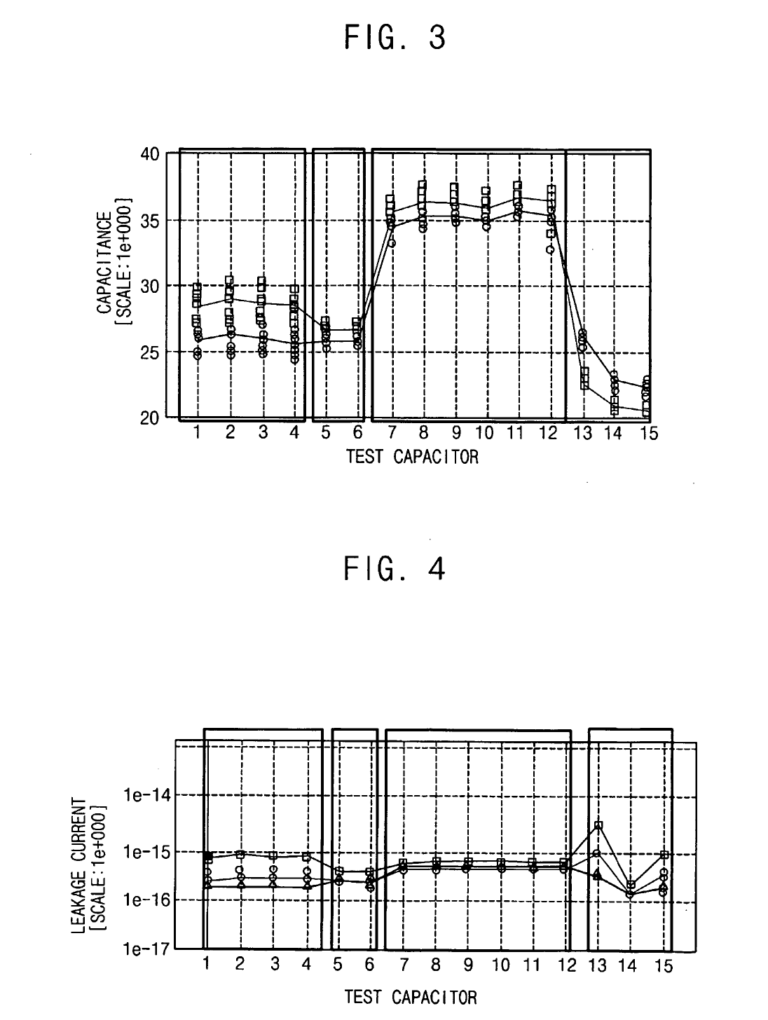

FIG. 4 is a graph illustrating a leakage current measured from various test capacitors. In FIG. 4, test capacitors 1 to 15 may be the same as those utilized for the above evaluation of the capacitance, so that any further detailed description on the test capacitors may be omitted hereinafter. As shown in FIG. 13, the results of the capacitance measurement show that test capacitors 5 and 6 including the SIM structure of example embodiments of the present invention may have the most allowable current leakage characteristics among the test capacitors.

According to example embodiments of the present invention, a SIM-structured capacitor may include a lower electrode comprising metal, a dielectric layer comprising metal oxide and an upper electrode formed into a multilayer structure using a polycrystalline semiconductor Group IV material. As a result, the SIM-structured capacitor of example embodiments of the present invention may have a sufficiently small EOT and sufficiently improved current leakage characteristics.

Therefore, a semiconductor device including the capacitor of example embodiments of the present invention may have improved electrical reliability.

The foregoing is illustrative of example embodiments of the present invention and is not to be construed as limiting thereof. Although a few example embodiments of the present invention have been described, those skilled in the art will readily appreciate that many modifications may be possible in the example embodiments without materially departing from the novel teachings and advantages of example embodiments of the present invention. Accordingly, all such modifications are intended to be included within the scope of example embodiments of the present invention as defined in the claims. In the claims, means-plus-function clauses are intended to cover the structures described herein as performing the recited function and not only structural equivalents but also equivalent structures. Therefore, it is to be understood that the foregoing is illustrative of example embodiments of the present invention and is not to be construed as limited to the specific embodiments disclosed, and that modifications to the disclosed embodiments, as well as other embodiments, are intended to be included within the scope of the appended claims. Example embodiments of the present invention are defined by the following claims, with equivalents of the claims to be included therein.

What is claimed is:

1. A capacitor comprising:
a lower electrode on a semiconductor substrate;
a dielectric layer on the lower electrode; and
an upper electrode on the dielectric layer, the upper electrode having a multilayer structure including a polycrystalline semiconductor Group IV material.

2. The capacitor of claim 1, wherein the polycrystalline semiconductor Group IV material includes silicon, germanium or a combination thereof.

3. The capacitor of claim 1, wherein the multilayer structure of the upper electrode includes one of a first combination of a first layer comprising silicon and a second layer comprising silicon germanium, a second combination of a first layer comprising germanium and a second layer comprising silicon germanium, a third combination of a first layer comprising silicon germanium and a second layer comprising silicon, and a fourth combination of a first layer comprising silicon germanium and a second layer comprising germanium.

4. The capacitor of claim 3, wherein an atomic ratio of germanium with respect to silicon in the silicon germanium ranges from about 0.0001 to about 10,000.

5. The capacitor of claim 1, wherein the upper electrode is formed at a temperature of below about 500° C.

6. The capacitor of claim 5, wherein the upper electrode is formed at a temperature of about 400° C. to about 500° C.

7. The capacitor of claim 1, wherein the upper electrode is formed by a low pressure chemical vapor deposition (LPCVD) process.

8. The capacitor of claim 1, wherein the upper electrode further includes at least one of a Group III semiconductor material and a Group V semiconductor material.

9. A method of manufacturing a capacitor, comprising:
forming a lower electrode on a semiconductor substrate;
forming a dielectric layer on the lower electrode; and
forming an upper electrode on the dielectric layer into a multilayer structure including a polycrystalline semiconductor Group IV material.

10. The method of claim 9, wherein the polycrystalline semiconductor Group IV material includes silicon, germanium or a combination thereof.

11. The method of claim 9, wherein the multilayer structure of the upper electrode includes one of a first combination of a first layer comprising silicon and a second layer comprising silicon germanium, a second combination of a first layer comprising germanium and a second layer comprising silicon germanium, a third combination of a first layer comprising silicon germanium and a second layer comprising silicon, and a fourth combination of a first layer comprising silicon germanium and a second layer comprising germanium.

12. The method of claim 11, wherein an atomic ratio of germanium with respect to silicon ranges from about 0.0001 to about 10,000.

13. The method of claim 9, wherein the upper electrode is formed at a temperature of below about 500° C.

14. The method of claim 13, wherein forming the upper electrode is performed at a temperature of about 400° C. to about 500° C.

15. The method of claim 9, further including doping at least one of a Group III semiconductor material and a Group V semiconductor material onto the upper electrode including the polycrystalline semiconductor Group IV material.

16. A method of forming a capacitor, comprising:
forming an insulation layer pattern having an opening on a semiconductor substrate;
continuously forming a lower electrode layer on a sidewall and a bottom of the opening and a top surface of the insulation layer pattern, the lower electrode layer including metal;
forming a sacrificial layer on the substrate including the lower electrode layer to a sufficient thickness to fill the opening;
partially removing the sacrificial layer until the top surface of the insulation layer pattern is exposed, so that the sacrificial layer remains only in the opening;
removing the remaining sacrificial layer and the insulation layer pattern from the substrate to thereby form a cylindrical lower electrode on the substrate;
forming a dielectric layer on the lower electrode, the dielectric layer including metal oxide; and
forming an upper electrode into a multilayer structure on the dielectric layer, the multilayer structure including a first layer including a first polycrystalline semiconductor Group IV material and a second layer including the first semiconductor material and a second polycrystalline semiconductor Group IV material, the second semiconductor material being different from the first semiconductor material.

17. The method of claim 16, wherein the lower electrode layer is selected from the group including titanium, titanium nitride, tantalum, tantalum nitride, ruthenium, tungsten, tungsten nitride, platinum, ruthenium oxide, or strontium ruthenium oxide.

18. The method of claim 16, wherein the sacrificial layer includes one of an oxide layer and a photoresist layer.

19. The method of claim 16, wherein the dielectric layer is formed from one oxide, one oxynitride, or a combination of one oxide and one oxynitride of the group including aluminum oxide (AlO₃), hafnium oxide (HfO₂), tantalum oxide (Ta₂O₅), zirconium oxide (ZrO₂), hafnium silicon oxide (HfSiO₂), zirconium silicon oxide (ZrSiO), titanium oxide (TiO₂), lanthanum oxide (LaO), lead titanium oxide (PbTiO₃), lead zirconium titanium oxide [Pb(Zr,Ti)O₃], strontium titanium oxide (SrTiO₃), barium strontium titanium oxide [(Ba,Sr)TiO₃], aluminum oxynitride, hafnium oxynitride, tantalum oxynitride, zirconium oxynitride, hafnium silicon oxynitride, zirconium silicon oxynitride, titanium oxynitride, and lanthanum oxynitride.

20. The method of claim 16, further comprising:
doping a first Group III or Group V semiconductor material onto the first layer of the multilayer structure; and
doping a second Group III or Group V semiconductor material onto the second layer of the multilayer structure.
